(19) United States
(12) Patent Application Publication
(10) Pub. No.: US 2019/0123074 A1
(43) Pub. Date: Apr. 25, 2019

(54) Semiconductor Device and Preparation Method thereof

(71) Applicant: Huaian Imaging Device Manufacturer Corporation, Huaian (CN)

(72) Inventors: Shijie CHEN, Huaian (CN); Xiaolu HUANG, Huaian (CN)

(21) Appl. No.: 16/051,121

(22) Filed: Jul. 31, 2018

(30) Foreign Application Priority Data
Oct. 20, 2017 (CN) 201710986571.0

(51) Int. Cl. H01L 27/146

(52) U.S. Cl. CPC H01L 27/1464; H01L 27/14685; H01L 27/14687; H01L 27/1463; H01L 27/14636; H01L 27/1462

(57) ABSTRACT

The application disclosed a semiconductor image sensor and a preparation method thereof. The semiconductor image sensor includes: a semiconductor substrate, a buffer layer formed on the semiconductor substrate; and a potential regulation laminated structure, formed on the buffer layer, and configured to regulate a surface potential of the semiconductor substrate. The potential regulation laminated structure includes a first potential regulation layer formed on the buffer layer, a second potential regulation layer formed on the first potential regulation layer and a third potential regulation layer formed on the second potential regulation layer, wherein the first potential regulation layer includes a high-k dielectric constant material layer, and the second and third potential regulation layers each include either a conductive material layer or a high-k dielectric constant material layer.

### CROSS REFERENCES TO RELATED APPLICATIONS

This application claims the benefit of priority to Chinese Patent Application No. CN201710986571.0, entitled “Semiconductor Device and Preparation Method Thereof”, filed with SIPO on Oct. 20, 2017, the contents of which are incorporated herein by reference in its entirety.

### TECHNICAL FIELD

The present disclosure relates to the technical field of semiconductors, and in particular, to a semiconductor device and a preparation method thereof.

### BACKGROUND

Image sensors based on semiconductor technology have been widely used in digital cameras, PC cameras, video phones, mobile phones, video conferences, smart security systems, car sensors, toys, and other industrial and medical devices.

Image sensors in mobile phones are generally used as front side illumination (FSI) image sensors and backside illumination (BSI) image sensors. A backside illumination image sensor receives light from its back surface, when illuminating light is emitted into a back surface of the sensor substrate. Components in a mobile phone that may affect receiving the illuminating light such as a wiring layer are designed to be on a front surface of the substrate. Thus, the light may be received without passing through the wiring layer. Compared with a front side illumination image sensor, a backside illumination image sensor may greatly reduce the impacts from direct light scatterings and crosstalk from the front.

As for any detectors, low dark current on a backside illumination image sensor is an important indicator of the sensor quality. A dark current indicates electron leaks from material defects, traps, charges, or dangling bonds in the sensor material such as a silicon substrate for the semiconductor image sensors. Reducing dark current on the sensor will improve BSI image quality.

BSIs are often made of silicon photodiodes. In order to reduce dark current, one conventional method applies a surface barrier formed on the surface of the silicon substrate by ion implanting dopants into the substrate to increase the surface barrier for leaky electrons. However, this method also reduces the full well capacity (FWC) of an image sensor. FWC refers to the maximum number of electrons that can be borne in a photodiode capacitor, and FWC is an important parameter for ranking the performance of the photodiode, and ion implantation may create crystalline damages, thus causing FWC reduction. There is a need to build backside illumination image sensor having low dark current.

### SUMMARY

The present disclosure provides a semiconductor image sensor and methods of making it. The semiconductor sensor includes a substrate a buffer layer on the semiconductor substrate; a potential regulation laminated structure, formed on the buffer layer, and configured to regulate a surface potential of the semiconductor substrate, and a dielectric protection layer formed on the potential regulation laminated structure. The potential regulation laminated structure comprises a first potential regulation layer formed on the buffer layer and a second potential regulation layer formed on the first potential regulation layer, wherein the first potential regulation layer comprises a high-k dielectric constant material layer. The second potential regulation layer includes either a high-k dielectric constant material layer or a conductive layer.

Optionally, the semiconductor device further comprises an anti-reflection layer which is formed on the dielectric protection layer.

Optionally, the potential regulation laminated structure further comprises a third potential regulation layer, the third potential regulation layer is formed on the second potential regulation layer and formed between the second potential regulation layer and the dielectric protection layer.

Optionally, the third potential regulation layer comprises a high-k dielectric constant material layer or a conductive material layer.

Optionally, the semiconductor substrate comprises trenches and light-sensitive regions separated by the trenches, the buffer layer covers the surface of the trench and the surfaces of the light-sensitive regions.

Optionally, the depth-to-width ratio of the trench is greater than or equal to 5:1.

Optionally, the semiconductor device further comprises a filling layer, the filling layer fills up the trench.

Optionally, the semiconductor device further comprises sensing units, the sensing units are located in the semiconductor substrate and corresponding to the light-sensitive regions upper to lower.

Optionally, the semiconductor device is a backside illumination image sensor, the sensing units is located on a front surface of the semiconductor substrate, the trenches and the light-sensitive regions are located on a back surface of the semiconductor substrate, and the buffer layer being formed on the back surface of the semiconductor substrate.

The present disclosure also provides a preparation method for a semiconductor device. The preparation method for a semiconductor device comprises the following steps:

1) providing a semiconductor substrate;

2) forming a buffer layer on the semiconductor substrate; and

3) forming a potential regulation laminated structure on the buffer layer, wherein step 3) comprising: forming a high-k dielectric constant material layer on the buffer layer to serve as a first potential regulation layer, and forming a conductive material layer or a high-k dielectric constant material layer on the first potential regulation layer to serve as a second potential regulation layer.

Optionally, the semiconductor substrate provided in step 1) comprises a front surface and a back surface opposite to each other, the buffer layer formed in step 2) is on the back surface of the semiconductor substrate, and between step 1) and step 2), there are also the following steps: forming a plurality of sensing units arranged at intervals in the semiconductor substrate from the front surface of the semiconductor substrate; forming a wiring layer on the front surface of the semiconductor substrate, the wiring layer comprising an inter level dielectric layer located on the front surface of the semiconductor substrate and an interconnecting wire layer located in the interlevel dielectric layer; providing a supporting substrate, and bonding the semiconductor substrate to the supporting substrate, a bonding surface is the surface of the wiring layer which is away from the semiconductor substrate; and then thinning the semiconductor substrate from the back surface of the semiconductor substrate.

Optionally, after thinning the semiconductor substrate from the back surface, the method further comprises a step of forming trenches in the semiconductor substrate from the back surface of the semiconductor substrate, the trenches separate a plurality of light-sensitive regions in the semiconductor substrate, and the light-sensitive regions and the sensing units are in upper to lower correspondence one by one, wherein the buffer layer formed in step 2) covers the surface of the trench and the surfaces of the light-sensitive regions.

Optionally, after step 3), the method further comprises a step of forming a filling layer on the potential regulation laminated structure, the filling layer filling up the trench.

Optionally, after forming a conductive material layer or a high-k dielectric constant material layer on the first potential regulation layer to serve as a second potential regulation layer, the method further comprises a step of forming a third potential regulation layer on the second potential regulation layer.

Optionally, the third potential regulation layer comprises a high-k dielectric constant material layer or a conductive material layer.

Optionally, after step 3), the method further comprises a step of forming a dielectric protection layer on the potential regulation laminated structure.

Optionally, after forming the dielectric protection layer on the potential regulation laminated structure, the method further comprises a step of annealing the obtained structure.

Optionally, after annealing, the method further comprises a step of forming an anti-reflection layer on the dielectric protection layer.

Optionally, after forming the dielectric protection layer on the potential regulation laminated structure, the method further comprises a step of forming an anti-reflection layer on the dielectric protection layer.

Optionally, after forming an anti-reflection layer on the dielectric protection layer, the method further comprises a step of annealing the obtained structure.

### BRIEF DESCRIPTION OF THE DRAWINGS

FIG. 1 shows a flowchart of steps in preparing for a semiconductor substrate prior to sensor patterning, according to an embodiment of the present disclosure.

FIG. 2 to FIG. 7 show cross sectional views of multiple steps in forming the semiconductor substrate according to an embodiment in FIG. 1.

FIG. 8 to FIG. 15 disclose cross sectional views of steps in preparing for image sensors on a semiconductor substrate disclosed in FIGS. 2-7, according to another embodiment.

FIG. 16 shows a cross sectional view of image sensors built on a semiconductor substrate according to yet another embodiment.

### LIST OF REFERENCE NUMERALS OF COMPONENTS

11 Semiconductor substrate
12 Buffer layer
13 Potential regulation laminated structure
131 First potential regulation layer
132 Second potential regulation layer
133 Third potential regulation layer
14 Dielectric protection layer
15 Anti-reflection layer
16 Trench
17 Light-sensitive region
18 Filling layer

### DETAILED DESCRIPTION OF THE PREFERRED EMBODIMENTS

The foregoing objectives, features, and advantages of the present disclosure will become more apparent from the following detailed description of specific embodiments of the disclosure in conjunction with the accompanying drawings. In the detailed description of the embodiments of the present disclosure, for convenience of description, the schematic diagram will be partially enlarged not according to an ordinary ratio, and the schematic diagram is only an example, which should not limit the protection scope of the present disclosure. In addition, three-dimensional space dimensions of length, width, and depth should be comprised in actual production.

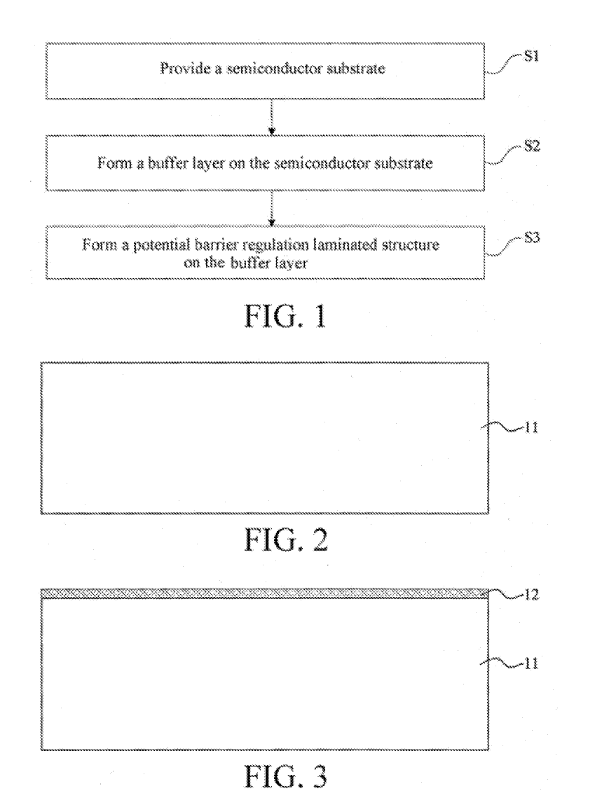

Please refer to FIG. 1 to FIG. 16. It should be noted that the illustration provided in the present embodiment merely illustrates the basic concept of the present disclosure by way of illustration. Although only components related to the present disclosure are shown in the illustration, the number, shape and size drawing of the components in actual implementation are not limited. The form, quantity and proportion of various components in actual implementation may be randomly changed, and the layout of the components may also be more complicated.

### Embodiment 1

The present disclosure provides a preparation method for a semiconductor device. Please refer to FIG. 1, the method comprises the following steps:

1) providing a semiconductor substrate;

2) forming a buffer layer on the semiconductor substrate;

3) forming a potential regulation laminated structure on the buffer layer.

Wherein in step 3), forming a potential regulation laminated structure on the buffer layer comprises following steps: forming a high-k dielectric constant material layer on the buffer layer to serve as a first potential regulation layer, and then forming a conductive material layer or a high-k dielectric constant material layer on the first potential regulation layer to serve as a second potential regulation layer.

In step 1), referring to S1 in FIG. 1 and FIG. 2, a semiconductor substrate 11 is provided.

As an example, the semiconductor substrate 11 may be a silicon substrate, a sapphire substrate, a gallium nitride substrate, or the like. Preferably, in the present embodiment, the semiconductor substrate 11 is a silicon substrate. A plurality of sensing units (not shown) arranged at intervals may be formed in the semiconductor substrate 11, where the sensing unit may comprise a diode and an MOS device. The sensing unit may be adjacent to a front surface of the semiconductor substrate 11. That is, the sensing unit may be located within a front surface of the semiconductor substrate 11, or may partially protrude from the front surface of the semiconductor substrate 11.

As an example, the semiconductor substrate 11 may be a thinned substrate, or may be a non-thinned substrate. When the semiconductor substrate 11 is anon-thinned substrate, after step 1), the method further comprises a step of thinning the semiconductor substrate 11 from a back surface. Specifically, the semiconductor substrate 11 may be thinned by a mechanical grinding process and/or a chemical thinning process. The thickness of the semiconductor substrate 11 remained after thinning may be determined according to actual requirements. More specifically, between step 1) and step 2), there are following steps:

forming a plurality of sensing units (not shown) arranged at intervals in the semiconductor substrate 11 from the front surface of the semiconductor substrate 11;

forming a wiring layer (not shown) on the front surface of the semiconductor substrate 11, the wiring layer comprising an interlevel dielectric layer (not shown) located on the front surface of the semiconductor substrate 11 and an interconnecting wire layer (not shown) located in the interlevel dielectric layer;

providing a supporting substrate (not shown), and bonding the semiconductor substrate to the supporting substrate, a bonding surface is the surface of the wiring layer which is away from the semiconductor substrate; and

thinning the semiconductor substrate 11 from the back surface of the semiconductor substrate 11.

In step 2), referring to S2 in FIG. 1 and FIG. 3, a buffer layer 12 is formed on the semiconductor substrate 11.

As an example, the buffer layer 12 may be dielectric material layer with a low dielectric constant (low-k), for example, silicon dioxide. The thickness of the buffer layer 12 may be set according to actual requirements. Preferably, the thickness of the buffer layer 12 may be within a range of 1 nm to 10 nm. More preferably, in the present embodiment, the thickness of the buffer layer 12 is 3 nm. The buffer layer 12 may be formed by means of a chemical vapor deposition (CVD) process, an atomic layer deposition (ALD) process, a thermal oxidation process, or other suitable process technologies.

As an example, the buffer layer 12 may be formed on the back surface of the semiconductor substrate 11.

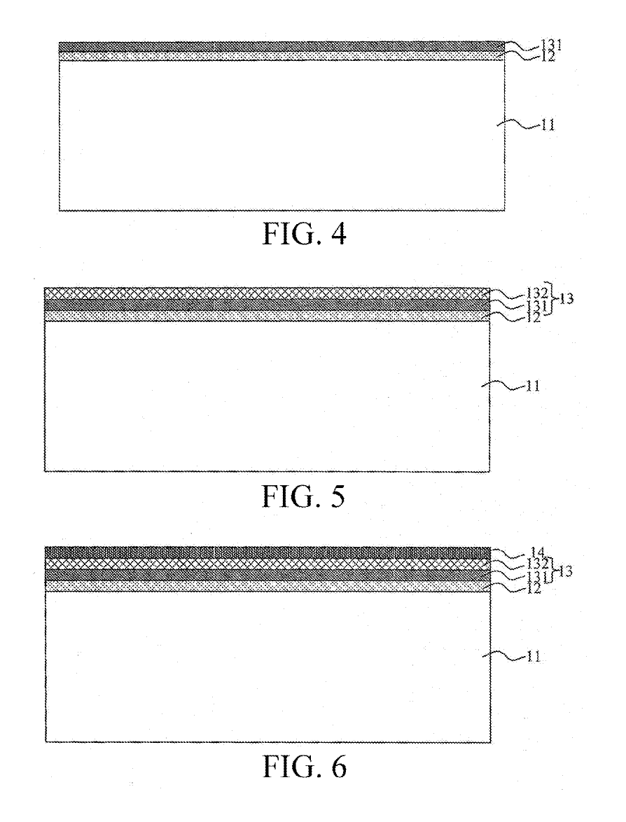

In step 3), referring to S3 in FIG. 1 as well as FIG. 4 and FIG. 5, the method of forming a potential regulation laminated structure 13 on the buffer layer 12 specifically comprises: forming a high-k dielectric constant material layer on the buffer layer 12 to serve as a first potential regulation layer 131.

In step 4), forming a conductive material layer or a high-k dielectric constant material layer on the first potential regulation layer 131 to serve as a second potential regulation layer 132.

As an example, the first potential regulation layer 131 may be a metal oxide layer with a high-k dielectric constant (high-k), and the first potential regulation layer 131 may be made of aluminum oxide, hafnium oxide, lanthanum oxide, zirconium oxide, hafnium aluminate, or the like. The thickness of the first potential regulation layer 131 may be set according to actual requirements. Preferably, the thickness of the first potential regulation layer 131 may be within a range of 1 nm to 20 nm. More preferably, the thickness of the first potential regulation layer 131 may be within a range of 6 nm to 10 nm. Most preferably, in the present embodiment, the thickness of the first potential regulation layer 131 is 6.6 nm. The first potential regulation layer 131 may be formed by means of a chemical vapor deposition process, an atomic layer deposition process, or a metal organic chemical vapor deposition (MOCVD) process.

As an example, the second potential regulation layer 132 and the first potential regulation layer 131 are made of different materials, the second potential regulation layer 132 may be a metal layer, a metal oxide layer, or a metal nitride layer, and the second potential regulation layer 132 may be made of aluminum, titanium, titanium nitride, tantalum, tantalum nitride, tantalum oxide, or the like. The thickness of the second potential regulation layer 132 may be set according to actual requirements. Preferably, the thickness of the second potential regulation layer 132 may be within a range of 1 nm to 20 nm. More preferably, the thickness of the second potential regulation layer 132 may be within a range of 1 nm to 10 nm. Most preferably, in the present embodiment, the thickness of the second potential regulation layer 132 is 3 nm. The second potential regulation layer 132 may be formed by means of a chemical vapor deposition process, an atomic layer deposition process, or a metal organic chemical vapor deposition (MOCVD) process.

As an example, the material of the first potential regulation layer 131 and the material of the second potential regulation layer 132 may contain a same metallic element. Of course, in other examples, the material of the first potential regulation layer 131 and the material of the second potential regulation layer 132 may also contain different metallic elements.

As an example, as shown in FIG. 6, after step 3), that is, after forming a potential regulation laminated structure 13 on the buffer layer 12, the method further comprises a step of forming a dielectric protection layer 14 on the potential regulation laminated structure 13. Specifically, the dielectric protection layer 14 may be a dielectric material layer with a low dielectric constant, for example, silicon dioxide. The thickness of the dielectric protection layer 14 may be set according to actual requirements. Preferably, the thickness of the dielectric protection layer 14 may be within a range of 1 nm to 50 nm. More preferably, in the present embodiment, the thickness of the dielectric protection layer 14 is 4 nm. The dielectric protection layer 14 may be formed by means of a chemical vapor deposition (CVD) process, an atomic layer deposition (ALD) process, a thermal oxidation process, or other suitable process technologies.

In an example, after forming a dielectric protection layer 14 on the potential regulation laminated structure 13, the method further comprises a step of annealing, that is, annealing the structure comprising the semiconductor substrate 11, the first potential regulation layer 131, the second potential regulation layer 132 and the dielectric protection layer 14 successively stacked. Specifically, the annealing temperature is within a range of 400° C. to 1,000° C., and the annealing time may be set as needed. Preferably, the annealing time may be within a range of 10 s to 120 min. The annealing atmosphere may be set according to actual requirements. Preferably, the obtained structure may be annealed under a nitrogen atmosphere or an oxygen atmosphere. By annealing, electric dipoles may be formed between the buffer layer 12 and the first potential regulation layer 131, between the first potential regulation layer 131 and the second potential regulation layer 132, and between the second potential regulation layer 132 and the dielectric protection layer 14. The electric dipoles may form a charge barrier, so as to limit adverse effects caused by, for example, dangling bonds at an interface or other surface defects, thereby regulating (e.g., improving) the surface electron potential of the semiconductor substrate 11, and reducing the occurrence probability of dark current caused by energy level transition of electrons on the surface of the semiconductor substrate 11.

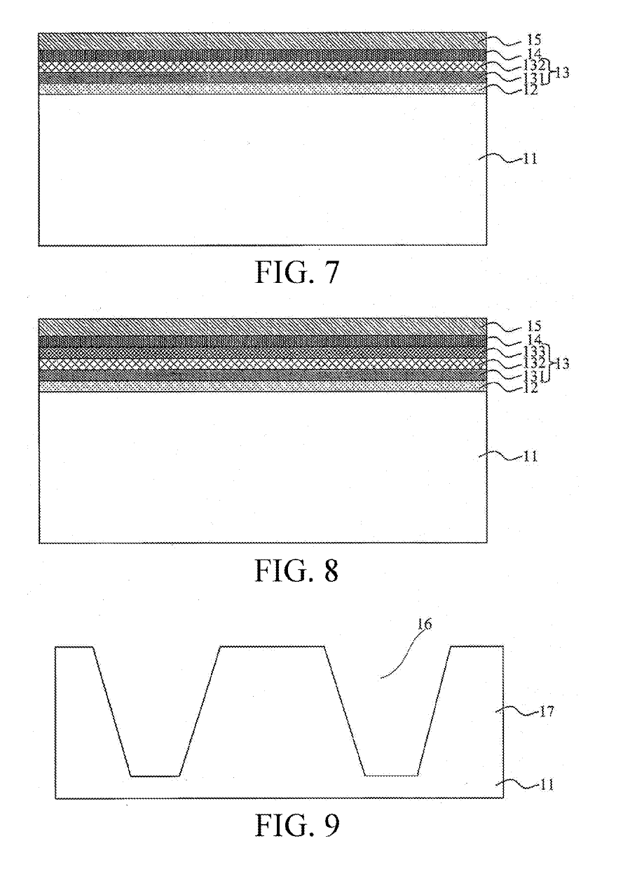

As an example, as shown in FIG. 7, after annealing, the method further comprises a step of forming an anti-reflection layer 15 on the dielectric protection layer 14. The anti-reflection layer 15 may be, but not limited to, a high-k dielectric constant material layer. The anti-reflection layer 15 may be made of silicon nitride, hafnium dioxide, or the like. Preferably, in the present embodiment, the anti-reflection layer 15 is made of silicon nitride. The thickness of the anti-reflection layer 15 may be set according to actual requirements. Preferably, the thickness of the anti-reflection layer 15 may be within a range of 10 nm to 200 nm. More preferably, the thickness of the anti-reflection layer 15 may be within a range of 20 nm to 170 nm. Most preferably, the thickness of the anti-reflection layer 15 is 70 nm. The anti-reflection layer 15 may be formed by means of a thermal oxidation process or a plasma enhanced chemical vapor deposition (PECVD) process.

In the present example, after the dielectric protection layer 14 is formed on the potential regulation laminated structure 13, an annealing process is performed, and then the anti-reflection layer 15 is formed on the dielectric protection layer 14. After these processes, the best interface repair and interface reaction effects are achieved, but since the isolating and protecting are performed only by the dielectric protection layer 14 during annealing and the thickness of the dielectric protection layer 14 is relatively small, the possibility of metal contamination to the environment will be greatly increased.

In another example, as shown in FIG. 7, after forming the dielectric protection layer 14 on the potential regulation laminated structure 13, the method further comprises a step of forming an anti-reflection layer 15 on the dielectric protection layer 14. The anti-reflection layer 15 may be, but not limited to, a high-k dielectric constant material layer. The anti-reflection layer 15 may be made of silicon nitride, hafnium dioxide, or the like. Preferably, in the present embodiment, the anti-reflection layer 15 is made of silicon nitride. The thickness of the anti-reflection layer 15 may be set according to actual needs. Preferably, the thickness of the anti-reflection layer 15 may be within a range of 10 nm to 200 nm. More preferably, the thickness of the anti-reflection layer 15 may be within a range of 20 nm to 170 nm. Most preferably, the thickness of the anti-reflection layer 15 is 70 nm. The anti-reflection layer 15 may be formed by means of a thermal oxidation process or a plasma enhanced chemical vapor deposition (PECVD) process.

After forming the anti-reflection layer 15 on the dielectric protection layer 14, the method further comprises a step of annealing, that is, annealing the structure comprising the semiconductor substrate 11, the first potential regulation layer 131, the second potential regulation layer 132, the dielectric protection layer 14, and the anti-reflection layer 15 successively stacked. Specifically, the annealing temperature is within a range of 400° C. to 1,000° C., and the annealing time may be set as needed. Preferably, the annealing time may be within a range of 10 s to 120 min. The annealing atmosphere may be set according to actual requirements. Preferably, the obtained structure may be annealed under a nitrogen atmosphere or an oxygen atmosphere. By annealing, electric dipoles may be formed between the buffer layer 12 and the first potential regulation layer 131, between the first potential regulation layer 131 and the second potential regulation layer 132, and between the second potential regulation layer 132 and the dielectric protection layer 14. The electric dipoles may form a charge barrier, so as to limit adverse effects caused by, for example, dangling bonds at an interface or other surface defects, thereby regulating (e.g., improving) the surface electron potential of the semiconductor substrate 11, and reducing the occurrence probability of forming a dark current by energy level transition of electrons on the surface of the semiconductor substrate 11.

In the present example, the annealing process is performed after the anti-reflection layer 15 is formed on the dielectric protection layer 14, better interface repair and interface reaction effects are achieved, and moreover, the isolating and protecting are performed by both the dielectric protection layer 14 and the anti-reflection layer 15 during annealing, so that the possibility of metal contamination to the environment will be greatly increased.

### Embodiment 2

Please refer to FIG. 7 again, the present embodiment further provides a semiconductor device, comprising: a semiconductor substrate 11; a buffer layer 12 formed on the semiconductor substrate 11; and a potential regulation laminated structure 13 formed on the buffer layer 12, and configured to regulate a surface potential of the semiconductor substrate 11, the potential regulation laminated structure 13 comprising a first potential regulation layer 131 formed on the buffer layer 12 and a second potential regulation layer 132 formed on the first potential regulation layer 131, wherein the first potential regulation layer 131 comprises a high-k dielectric constant material layer, and the second potential regulation layer 132 comprises a conductive material layer or a high-k dielectric constant material layer.

As an example, the semiconductor substrate 11 may be a silicon substrate, a sapphire substrate, a gallium nitride substrate, or the like. Preferably, in the present embodiment, the semiconductor substrate 11 is a silicon substrate. A plurality of sensing units (not shown) arranged at intervals may be formed in the semiconductor substrate 11, where the sensing unit may comprise a diode and an MOS device. The sensing unit may be adjacent to a front surface of the semiconductor substrate 11. That is, the sensing unit may be located within a front surface of the semiconductor substrate, or may partially protrude from the front surface of the semiconductor substrate 11.

As an example, the semiconductor substrate 11 may be a thinned substrate, or may be a non-thinned substrate.

As an example, the buffer layer 12 may be a dielectric material layer with a low dielectric constant (low-k), for example, silicon dioxide. The thickness of the buffer layer 12 may be set according to actual requirements. Preferably, the thickness of the buffer layer 12 may be within a range of 1 nm to 10 nm. More preferably, in the present embodiment, the thickness of the buffer layer 12 is 3 nm.

As an example, the first potential regulation layer 131 may be a metal oxide layer with a high-k dielectric constant (high-k), which may be made of aluminum oxide, hafnium oxide, lanthanum oxide, zirconium oxide, hafnium aluminate, or the like. The thickness of the first potential regulation layer 131 may be set according to actual requirements. Preferably, the thickness of the first potential regulation layer 131 may be within a range of 1 nm to 20 nm. More preferably, the thickness of the first potential regulation layer 131 may be within a range of 6 nm to 10 nm. Most preferably, in the present embodiment, the thickness of the first potential regulation layer 131 is 6.6 nm.

As an example, the second potential regulation layer 132 and the first potential regulation layer 131 are made of different materials, the second potential regulation layer 132 may be a metal layer, a metal oxide layer, or a metal nitride layer, and the second potential regulation layer 132 may be made of aluminum, titanium, titanium nitride, tantalum, tantalum nitride, tantalum oxide, or the like. The thickness of the second potential regulation layer 132 may be set according to actual requirements. Preferably, the thickness of the second potential regulation layer 132 may be within a range of 1 nm to 20 nm. More preferably, the thickness of the second potential regulation layer 132 may be within a range of 1 nm to 10 nm. Most preferably, in the present embodiment, the thickness of the second potential regulation layer 132 is 3 nm.

As an example, the material of the first potential regulation layer 131 and the material of the second potential regulation layer 132 may contain a same metallic element. Of course, in other examples, the material of the first potential regulation layer 131 and the material of the second potential regulation layer 132 may also contain different metallic elements.

As an example, the semiconductor device further comprises a dielectric protection layer 14 formed on the potential regulation laminated structure 13. In the present embodiment, the dielectric protection layer 14 is formed on the second potential regulation layer 132, and the dielectric protection layer 14 may be a dielectric material layer with a low dielectric constant, for example, silicon dioxide. The thickness of the dielectric protection layer 14 may be set according to actual requirements. Preferably, the thickness of the dielectric protection layer 14 may be within a range of 1 nm to 50 nm. More preferably, in the present embodiment, the thickness of the dielectric protection layer 14 is 4 nm.

As an example, the semiconductor device further comprises an anti-reflection layer 15, and the anti-reflection layer 15 is formed on the dielectric protection layer 14. The anti-reflection layer 15 may be, but not limited to, a high-k dielectric constant material layer. The anti-reflection layer 15 may be made of silicon nitride, hafnium dioxide, or the like. Preferably, in the present embodiment, the anti-reflection layer 15 is made of silicon nitride. The thickness of the anti-reflection layer 15 may be set according to actual requirements. Preferably, the thickness of the anti-reflection layer 15 may be within a range of 10 nm to 200 nm. More preferably, the thickness of the anti-reflection layer 15 may be within a range of 20 nm to 170 nm. Most preferably, the thickness of the anti-reflection layer 15 is 70 nm.

### Embodiment 3

Please refer to FIG. 8, the present embodiment also provides a preparation method for a semiconductor device. The preparation method for a semiconductor device in the present embodiment is substantially the same as the preparation method in Embodiment 1. The difference therebetween lies in that: in Embodiment 1, a specific method for forming a potential regulation laminated structure 13 on the buffer layer 12 comprises: forming a high-k dielectric constant material layer on the buffer layer 12 to serve as the first potential regulation layer 131, and forming a conductive material layer or a high-k dielectric constant material layer on the first potential regulation layer 131 to serve as the second potential regulation layer 132, the prepared potential regulation laminated structure 13 comprising the first potential regulation layer 131 and the second potential regulation layer 132 located on the first potential regulation layer 131, and the dielectric protection layer 14 being formed on the second potential regulation layer 132; while in the present embodiment, a specific method for forming a potential regulation laminated structure 13 on the buffer layer 12 comprises: forming a high-k dielectric constant material layer on the buffer layer 12 to serve as the first potential regulation layer 131, forming a conductive material layer or a high-k dielectric constant material layer on the first potential regulation layer 131 to serve as the second potential regulation layer 132, and forming a third potential regulation layer 133 on the second potential regulation layer 132, the prepared potential regulation laminated structure 13 comprising the first potential regulation layer 131, the second potential regulation layer 132 located on the first potential regulation layer 131, and the third potential regulation layer 133 located on the second potential regulation layer 132, and the dielectric protection layer 14 being formed on the third potential regulation layer 133. The structure of the finally obtained semiconductor device is as shown in FIG. 8. That is, compared with the specific method in Embodiment 1, the specific method for forming a potential regulation laminated structure 13 on the buffer layer 12 in the present embodiment adds the step of forming a third potential regulation layer 133 on the second potential regulation layer 132. Compared with Embodiment 1, the potential regulation laminated structure 13 in the present embodiment further comprises a third potential regulation layer 133. Other steps of the preparation method for a semiconductor device in the present embodiment are exactly the same as other steps of the preparation method for a semiconductor device in Embodiment 1. Please refer to Embodiment 1 for details, the description will not be repeated here.

In an example, the third potential regulation layer 133 may comprise a high-k dielectric constant material layer. Specifically, the third potential regulation layer 133 may be a metal oxide layer with a high-k dielectric constant (high-k), and the third potential regulation layer 133 may be made of aluminum oxide, hafnium oxide, lanthanum oxide, zirconium oxide, hafnium aluminate, or the like. Preferably, in the present embodiment, the third potential regulation layer 133 may be made of the same material as that in the first potential regulation layer 131. The thickness of the third potential regulation layer 133 may be set according to actual requirements. Preferably, the thickness of the third potential regulation layer 133 may be within a range of 1 nm to 20 nm. More preferably, the thickness of the third potential regulation layer 133 may be within a range of 6 nm to 10 nm. Most preferably, in the present embodiment, the thickness of the third potential regulation layer 133 is 6.6 nm. The third potential regulation layer 133 may be formed by means of a chemical vapor deposition process, an atomic layer deposition process, or a metal organic chemical vapor deposition (MOCVD) process.

In another example, the third potential regulation layer 133 may be a metal layer, a metal oxide layer, or a metal nitride layer, and the third potential regulation layer 133 may be made of aluminum, titanium, titanium nitride, tantalum, tantalum nitride, tantalum oxide, or the like. Preferably, the third potential regulation layer 133 and the second potential regulation layer 132 are made of the same material. The thickness of the third potential regulation layer 133 may be set according to actual requirements. Preferably, the thickness of the third potential regulation layer 133 may be within a range of 1 nm to 20 nm. More preferably, the thickness of the third potential regulation layer 133 may be within a range of 1 nm to 10 nm. Most preferably, in the present embodiment, the thickness of the third potential regulation layer 133 is 3 nm. The third potential regulation layer 133 may be formed by means of a chemical vapor deposition process, an atomic layer deposition process, or a metal organic chemical vapor deposition (MOCVD) process.

### Embodiment 4

Please refer to FIG. 8 again, the present embodiment also provides a semiconductor device. A specific structure of the semiconductor device provided in the present embodiment is substantially the same as a specific structure in Embodiment 2. The difference therebetween lies in that: in Embodiment 2, the potential regulation laminated structure 13 comprises the first potential regulation layer 131 formed on the buffer layer 12 and the second potential regulation layer 132 formed on the first potential regulation layer 131, and the dielectric protection layer 14 is formed on the second potential regulation layer 132; while in the present embodiment, the potential regulation laminated structure 13 comprises a first potential regulation layer 131 formed on the buffer layer 12, a second potential regulation layer 132 formed on the first potential regulation layer 131, and a third potential regulation layer 133 formed on the second potential regulation layer 132, and a dielectric protection layer 14 is formed on the third potential regulation layer 133. That is, compared with the potential regulation laminated structure 13 in the semiconductor device in Embodiment 2, the potential regulation laminated structure 13 in the present embodiment further comprises a third potential regulation layer 133. Other structures of the semiconductor device in the present embodiment are exactly the same as other structures of the semiconductor device in Embodiment 2. Please refer to Embodiment 2 for details, the description is not repeated here.

In an example, the third potential regulation layer 133 may comprise a high-k dielectric constant material layer. Specifically, the third potential regulation layer 133 may be a metal oxide layer with a high-k dielectric constant (high-k), and the third potential regulation layer 133 may be made of aluminum oxide, hafnium oxide, lanthanum oxide, zirconium oxide, hafnium aluminate, or the like. Preferably, in the present embodiment, the third potential regulation layer 133 and the first potential regulation layer 131 are made of the same material. The thickness of the third potential regulation layer 133 may be set according to actual requirements. Preferably, the thickness of the third potential regulation layer 133 may be within a range of 1 nm to 20 nm. More preferably, the thickness of the third potential regulation layer 133 may be within a range of 6 nm to 10 nm. Most preferably, in the present embodiment, the thickness of the third potential regulation layer 133 is 6.6 nm.

In another example, the third potential regulation layer 133 may be a metal layer, a metal oxide layer, or a metal nitride layer, and the third potential regulation layer 133 may be made of aluminum, titanium, titanium nitride, tantalum, tantalum nitride, tantalum oxide, or the like. Preferably, the third potential regulation layer 133 and the second potential regulation layer 132 are made of the same material. The thickness of the third potential regulation layer 133 may be set according to actual requirements. Preferably, the thickness of the third potential regulation layer 133 may be within a range of 1 nm to 20 nm. More preferably, the thickness of the third potential regulation layer 133 may be within a range of 1 nm to 10 nm. Most preferably, in the present embodiment, the thickness of the third potential regulation layer 133 is 3 nm.

### Embodiment 5

Please refer to FIG. 9 to FIG. 15, the present embodiment also provides a preparation method for a semiconductor device. The preparation method for a semiconductor device in the present embodiment is substantially the same as the preparation method in Embodiment 1. The difference therebetween lies in that: in Embodiment 1, the back surface of the semiconductor substrate 11 is a non-trenched plane, and the buffer layer 12 covers the whole back surface of the semiconductor substrate 11; while in the present embodiment, after executing step 1) and before executing step 2) in Embodiment 1, the method further comprises a step of forming trenches 16 in the semiconductor substrate 11 from the back surface of the semiconductor substrate 11, the trenches 16 separates a plurality of light-sensitive regions 17 in the semiconductor substrate 11, and the light-sensitive regions 17 and the sensing units are in upper and lower correspondence one by one, as shown in FIG. 9.

As an example, the depth-to-width ratio of the trench 16 may be set according to actual requirements, and an appropriate depth-to-width ratio or sidewall tilt angle is conducive to separation and subsequent processing. The depth-to-width ratio of the trench 16 may be greater than or equal to 5:1. Preferably, the depth-to-width ratio of the trench 16 may be within a range of 5:1 to 30:1. More preferably, the depth-to-width ratio of the trench 16 may be within a range of 5:1 to 20:1.

As an example, the shape of the cross section of the trench 16 may be an inverted trapezoidal shape, a rectangle, a U shape, or the like according to an actual choice. In FIG. 9, the inverted trapezoidal shape of the trench 16 is taken as an example.

It should be noted that although only two trenches 16 and the light-sensitive regions 17 separated by the trenches 16 are illustrated in FIG. 9, those skilled in the art will readily understand that a random number of the trenches 16 and the light-sensitive regions 17 may be formed in the semiconductor substrate 11 as needed and will not be limited herein.

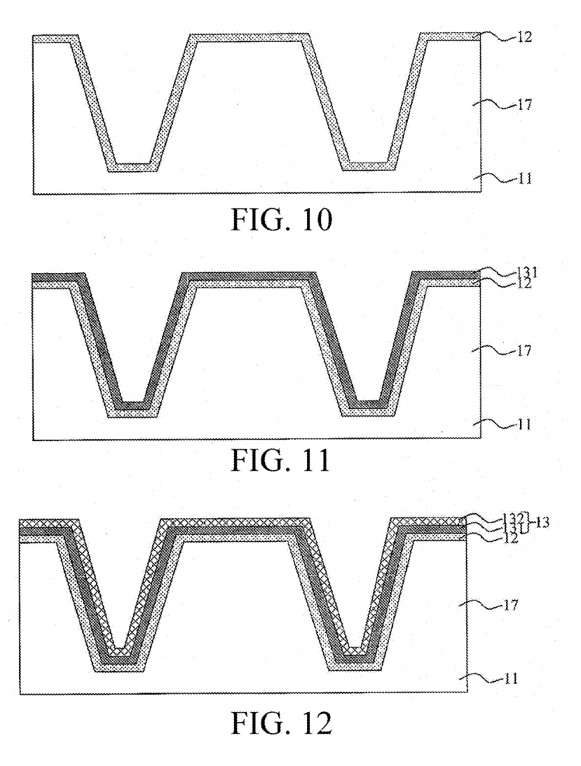

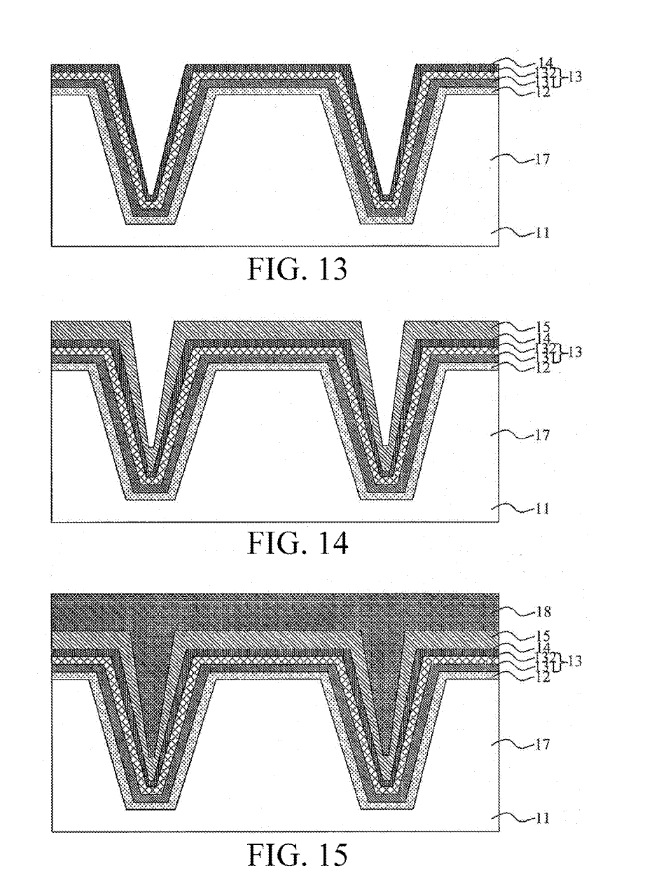

As an example, the buffer layer 12 formed in step 2) covers the surface of the trench 16 and the surface of the light-sensitive region 17, as shown in FIG. 10. The first potential regulation layer 131 formed in steps 3) and 4) covers the surface of the buffer layer 12 located on the surface of the trench 16 and the surface of the light-sensitive region 17, as shown in FIG. 11. The second potential regulation layer 132 covers the surface of the first potential regulation layer 131 located in the trench 16 and the light-sensitive region 17, as shown in FIG. 12. Both the dielectric protection layer 14 and the anti-reflection layer 15 cover the trench 16 and the light-sensitive region 17, as shown in FIG. 13 and FIG. 14. After forming the anti-reflection layer 15, the trench 16 is not filled up, as shown in FIG. 14. At this time, after forming the anti-reflection layer 15, the method further comprises a step of forming a filling layer 18 on the anti-reflection layer 15, the filling layer 18 filling up the trench, so as to ensure that the surface of the obtained structure is a plane, as shown in FIG. 15.

As an example, the filling layer 18 may be a dielectric material layer with a low dielectric constant, for example, silicon dioxide. The thickness of the filling layer 18 may be set according to actual requirements. Preferably, the filling layer 18 is 100 nm to 500 nm higher than the surface of the anti-reflection layer 15. More preferably, in the present embodiment, the filling layer 18 is 200 nm higher than the surface of the anti-reflection layer 15. The filling layer 18 may be formed by means of an atomic layer deposition process or a high aspect ratio process (Harp).

### Embodiment 6

Please refer to FIG. 15 again, the present embodiment also provides a semiconductor device. A specific structure of the semiconductor device in the present embodiment is substantially the same as a specific structure of the semiconductor device in Embodiment 1. The difference therebetween lies in that: in Embodiment 1, the back surface of the semiconductor substrate 11 is a non-trenched plane, and the buffer layer 12 covers the whole back surface of the semiconductor substrate 11; while in the present embodiment, trenches 16 are formed in the back surface of the semiconductor substrate 11, the trenches 16 separate a plurality of light-sensitive regions 17 in the semiconductor substrate 11, and the light-sensitive regions 17 and the sensing units are in upper and lower correspondence one by one. The buffer layer 12 covers the surface of the trench 16 and the surface of the light-sensitive region 17, the first potential regulation layer 131, the second potential regulation layer 132, the dielectric protection layer 14 and the anti-reflection layer 15 all cover the trench 16 and the light-sensitive regions 17, and after forming the anti-reflection layer 15, the trench 16 is not filled up. The semiconductor device in the present embodiment further comprises a filling layer 18, the filling layer 18 filling up the trench, so as to ensure that the surface of the obtained structure is a plane, as shown in FIG. 15.

As an example, the depth-to-width ratio of the trench 16 may be set according to actual requirements, and selection of an appropriate depth-to-width ratio or sidewall tilt angle is conducive to separation and subsequent processing. The depth-to-width ratio of the trench 16 may be greater than or equal to 5:1. Preferably, the depth-to-width ratio of the trench 16 may be within a range of 5:1 to 30:1. More preferably, the depth-to-width ratio of the trench 16 maybe within a range of 5:1 to 20:1.

As an example, the shape of the cross section of the trench 16 may be an inverted trapezoidal shape, a rectangle, a U shape, or the like according to an actual choice. In FIG. 9, the inverted trapezoidal shape of the trench 16 is taken as an example.

It should be noted that although only two trenches 16 and the light-sensitive regions 17 separated by the trenches 16 are illustrated in FIG. 9, those skilled in the art will readily understand that a random number of the trenches 16 and the light-sensitive regions 17 may be formed in the semiconductor substrate 11 as needed and will not be limited herein.

As an example, the filling layer 18 may be a dielectric material layer with a low dielectric constant, for example, silicon dioxide. The thickness of the filling layer 18 may be set according to actual needs. Preferably, the filling layer 18 is 100 nm to 500 nm higher than the surface of the anti-reflection layer 15. More preferably, in the present embodiment, the filling layer 18 is 200 nm higher than the surface of the anti-reflection layer 15. The filling layer 18 may be formed by means of an atomic layer deposition process or a high aspect ratio process (Harp).

### Embodiment 7

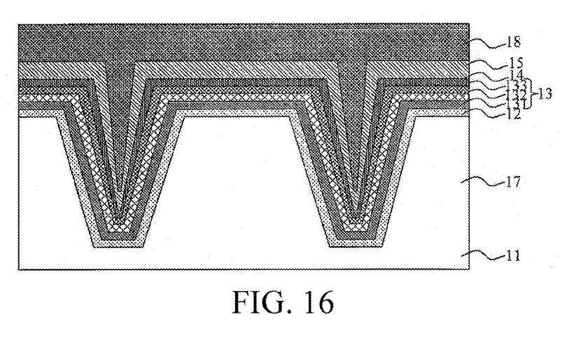

Please refer to FIG. 16, the present embodiment also provides a preparation method for a semiconductor device. The preparation method for a semiconductor device in the present embodiment is substantially the same as the preparation method in Embodiment 5. The difference therebetween lies in that: in Embodiment 5, a specific method for forming a potential regulation laminated structure 13 on the buffer layer 12 comprises: forming a high-k dielectric constant material layer on the buffer layer 12 to serve as the first potential regulation layer 131, and forming a conductive material layer or a high-k dielectric constant material layer on the first potential regulation layer 131 to serve as the second potential regulation layer 132, the prepared potential regulation laminated structure 13 comprising the first potential regulation layer 131 and the second potential regulation layer 132 located on the first potential regulation layer 131, and the dielectric protection layer 14 being formed on the second potential regulation layer 132; while in the present embodiment, a specific method of forming a potential regulation laminated structure 13 on the buffer layer 12 comprises: forming a high-k dielectric constant material layer on the buffer layer 12 to serve as the first potential regulation layer 131, forming a conductive material layer or a high-k dielectric constant material layer on the first potential regulation layer 131 to serve as the second potential regulation layer 132, and forming a third potential regulation layer 133 on the second potential regulation layer 132, the prepared potential regulation laminated structure 13 comprising the first potential regulation layer 131, the second potential regulation layer 132 located on the first potential regulation layer 131, and the third potential regulation layer 133 located on the second potential regulation layer 132, and the dielectric protection layer 14 being formed on the second potential regulation layer 132. The structure of the finally obtained semiconductor device is as shown in FIG. 16. That is, compared with the specific method in Embodiment 5, the specific method for forming a potential regulation laminated structure 13 on the buffer layer 12 in the present embodiment is added with the step of forming a third potential regulation layer 133 on the second potential regulation layer 132. Compared with Embodiment 5, the potential regulation laminated structure 13 in the present embodiment further comprises a third potential regulation layer 133. Other steps of the preparation method for a semiconductor device in the present embodiment are exactly the same as other steps of the preparation method for a semiconductor device in Embodiment 5. Please refer to Embodiment 5 for details, the description will not be repeated here.

In an example, the third potential regulation layer 133 may comprise a high-k dielectric constant material layer. Specifically, the third potential regulation layer 133 may be a metal oxide layer with a high-k dielectric constant (high-k), and the third potential regulation layer 133 may be made of aluminum oxide, hafnium oxide, lanthanum oxide, zirconium oxide, hafnium aluminate, or the like. Preferably, in the present embodiment, the third potential regulation layer 133 and the first potential regulation layer 131 are made of the same material. The thickness of the third potential regulation layer 133 may be set according to actual requirements. Preferably, the thickness of the third potential regulation layer 133 may be within a range of 1 nm to 20 nm. More preferably, the thickness of the third potential regulation layer 133 may be within a range of 6 nm to 10 nm. Most preferably, in the present embodiment, the thickness of the third potential regulation layer 133 is 6.6 nm. The third potential regulation layer 133 may be formed by means of a chemical vapor deposition process, an atomic layer deposition process, or a metal organic chemical vapor deposition (MOCVD) process.

In another example, the third potential regulation layer 133 may be a metal layer, a metal oxide layer, or a metal nitride layer, and the third potential regulation layer 133 may be made of aluminum, titanium, titanium nitride, tantalum, tantalum nitride, tantalum oxide, or the like. Preferably, the third potential regulation layer 133 and the second potential regulation layer 132 are made of the same material. The thickness of the third potential regulation layer 133 may be set according to actual requirements. Preferably, the thickness of the third potential regulation layer 133 may be within a range of 1 nm to 20 nm. More preferably, the thickness of the third potential regulation layer 133 may be within a range of 1 nm to 10 nm. Most preferably, in the present embodiment, the thickness of the third potential regulation layer 133 is 3 nm. The third potential regulation layer 133 may be formed by means of a chemical vapor deposition process, an atomic layer deposition process, or a metal organic chemical vapor deposition (MOCVD) process.

### Embodiment 8

Please refer to FIG. 16 again, the present embodiment also provides a semiconductor device. A specific structure of the semiconductor device provided in the present embodiment is substantially the same as a specific structure of the semiconductor device provided in Embodiment 6. The difference therebetween lies in that: in Embodiment 6, the potential regulation laminated structure 13 comprises the first potential regulation layer 131 formed on the buffer layer 12 and the second potential regulation layer 132 formed on the first potential regulation layer 131, and the dielectric protection layer 14 is formed on the second potential regulation layer 132; while in the present embodiment, the potential regulation laminated structure 13 comprises a first potential regulation layer 131 formed on the buffer layer 12, a second potential regulation layer 132 formed on the first potential regulation layer 131, and a third potential regulation layer 133 formed on the second potential regulation layer 132, and a dielectric protection layer 14 is formed on the third potential regulation layer 133. That is, compared with the potential regulation laminated structure 13 in the semiconductor device in Embodiment 6, the potential regulation laminated structure 13 in the present embodiment further comprises a third potential regulation layer 133. Other structures of the semiconductor device in the present embodiment are exactly the same as other structures of the semiconductor device in Embodiment 6. Please refer to Embodiment 6 for details, the description is not repeated here.

In an example, the third potential regulation layer 133 may comprise a high-k dielectric constant material layer. Specifically, the third potential regulation layer 133 may be a metal oxide layer with a high-k dielectric constant (high-k), and the third potential regulation layer 133 may be made of aluminum oxide, hafnium oxide, lanthanum oxide, zirconium oxide, hafnium aluminate, or the like. Preferably, in the present embodiment, the third potential regulation layer 133 and the first potential regulation layer 131 are made of the same material. The thickness of the third potential regulation layer 133 may be set according to actual requirements. Preferably, the thickness of the third potential regulation layer 133 may be within a range of 1 nm to 20 nm. More preferably, the thickness of the third potential regulation layer 133 may be within a range of 6 nm to 10 nm. Most preferably, in the present embodiment, the thickness of the third potential regulation layer 133 is 6.6 nm.

In another example, the third potential regulation layer 133 may be a metal layer, a metal oxide layer, or a metal nitride layer, and the third potential regulation layer 133 may be made of aluminum, titanium, titanium nitride, tantalum, tantalum nitride, tantalum oxide, or the like. Preferably, the third potential regulation layer 133 and the second potential regulation layer 132 are made of the same material. The thickness of the third potential regulation layer 133 may be set according to actual requirements. Preferably, the thickness of the third potential regulation layer 133 may be within a range of 1 nm to 20 nm. More preferably, the thickness of the third potential regulation layer 133 may be within a range of 1 nm to 10 nm. Most preferably, in the present embodiment, the thickness of the third potential regulation layer 133 is 3 nm.

In a summary, the present disclosure provides a semiconductor device and a preparation method thereof. The semiconductor device comprises: a semiconductor substrate; a buffer layer, formed on the semiconductor substrate; and a potential regulation laminated structure, formed on the buffer layer, and configured to regulate a surface potential of the semiconductor substrate, the potential regulation laminated structure comprising a first potential regulation layer formed on the buffer layer and a second potential regulation layer formed on the first potential regulation layer, wherein the first potential regulation layer comprises a high-k dielectric constant material layer, and the second potential regulation layer comprises a conductive material layer or a high-k dielectric constant material layer.

The technical solution of the present disclosure has the following advantages:

by forming a potential regulation laminated structure comprising a first potential regulation layer and a second potential regulation layer on a buffer layer, a larger work function difference between the potential regulation laminated structure and a semiconductor substrate may be realized, so that the surface potential of the semiconductor substrate is changed, and the occurrence of a dark current on the surface of the semiconductor substrate is reduced, thereby further suppressing the dark current, and improving the image quality.

The above embodiments merely illustrate the principle and effects of the present disclosure, but are not to limit the present disclosure. Any person skilled in the art can modify or vary the above embodiments without departing from the spirit and scope of the present disclosure. Accordingly, all equivalent modifications or variations completed by those with ordinary skill in the art without departing from the spirit and technical thought disclosed in the present disclosure should still be covered by the claims of the present disclosure.

1. A semiconductor image sensor, comprising:
a semiconductor substrate;
a buffer layer, formed on the semiconductor substrate;
a potential regulation laminated structure, formed on the buffer layer, and configured to regulate a surface potential of the semiconductor substrate; and
wherein the potential regulation laminated structure comprises a first potential regulation layer formed on the buffer layer and a second potential regulation layer formed on the first potential regulation layer, wherein the first potential regulation layer comprises a high-k dielectric constant material layer.

2. The semiconductor image sensor according to claim 1, further comprising a dielectric protection layer formed on the potential regulation laminated structure.

3. The semiconductor image sensor according to claim 1, wherein the second potential regulation layer comprises a conductive layer.

4. The semiconductor image sensor according to claim 1, wherein the second potential regulation layer comprises a high-k dielectric constant material layer.

5. The semiconductor image sensor according to claim 2, further comprising an anti-reflection layer formed on the dielectric protection layer.

6. The semiconductor image sensor according to claim 1, wherein the potential regulation laminated structure further comprises a third potential regulation layer, wherein the third potential regulation layer is formed between the second potential regulation layer and the dielectric protection layer.

7. The semiconductor image sensor according to claim 6, wherein the third potential regulation layer comprises a high-k dielectric constant material layer.

8. The semiconductor image sensor according to claim 6, wherein the third potential regulation layer comprises a conductive layer.

9. The semiconductor image sensor according to claim 1, wherein the semiconductor substrate comprises trenches and light-sensitive regions separated by the trenches, wherein the buffer layer covers the surfaces of the trenches and the surfaces of the light-sensitive regions.

10. The semiconductor image sensor according to claim 9, wherein the depth-to-width ratio of the trench is greater than or equal to 5:1.

11. The semiconductor image sensor according to claim 9, further comprising a filling layer, filling up the trench.

12. The semiconductor image sensor according to claim 9, further comprising sensing units, the sensing units are located in the semiconductor substrate and corresponding to the light-sensitive regions from top to bottom.

13. The semiconductor image sensor according to claim 12, wherein the semiconductor image sensor is a backside illumination image sensor, wherein the sensing units are located on a front surface of the semiconductor substrate, the trenches and the light-sensitive regions are located on a back surface of the semiconductor substrate, and the buffer layer are formed on the back surface of the semiconductor substrate.

14. A preparation method for a semiconductor image sensor, comprising the following steps:
1) providing a semiconductor substrate;
2) forming a buffer layer on the semiconductor substrate; and
3) forming a potential regulation laminated structure on the buffer layer,
wherein step 3) comprising: forming a high-k dielectric constant material layer on the buffer layer to serve as a first potential regulation layer, and forming a conductive material layer or a high-k dielectric constant material layer on the first potential regulation layer to serve as a second potential regulation layer.

15. The preparation method for the semiconductor image sensor according to claim 14, wherein the semiconductor substrate provided in step 1) comprises a front surface and a back surface opposite to each other, the buffer layer formed in step 2) is on the back surface of the semiconductor substrate, and between step 1) and step 2), the method further comprises the following steps:
forming a plurality of sensing units arranged at intervals in the semiconductor substrate from the front surface of the semiconductor substrate;
forming a wiring layer on the front surface of the semiconductor substrate, the wiring layer comprising an interlevel dielectric layer located on the front surface of the semiconductor substrate and an interconnecting wire layer located in the interlevel dielectric layer;
providing a supporting substrate, and bonding the semiconductor substrate to the supporting substrate, a bonding surface is the surface of the wiring layer which is away from the semiconductor substrate; and
thinning the semiconductor substrate from the back surface of the semiconductor substrate.

16. The preparation method for the semiconductor image sensor according to claim 15, wherein after thinning the semiconductor substrate from the back surface, the method further comprises a step of forming trenches in the semiconductor substrate from the back surface of the semiconductor substrate, the trenches separate a plurality of light-sensitive regions in the semiconductor substrate, and the light-sensitive regions and the sensing units are in upper to lower correspondence one by one, wherein the buffer layer formed in step 2) covers the surface of the trench and the surfaces of the light-sensitive regions; and forming a filling layer on the potential regulation laminated structure, filling up the trenches.

17. The preparation method for the semiconductor image sensor according to claim 14, the method further comprises a step of forming a third potential regulation layer on the second potential regulation layer, and a step of forming a dielectric protection layer on the potential regulation laminated structure.

18. The preparation method for the semiconductor image sensor according to claim 14, wherein the third potential regulation layer comprises a high-k dielectric constant material layer or a conductive material layer.

19. The preparation method for the semiconductor image sensor according to claim 14, wherein after step 3), the method further comprises a step of forming a dielectric protection layer on the potential regulation laminated structure and a step of annealing the obtained structure.

20. The preparation method for a semiconductor image sensor according to claim 19, wherein after annealing, the method further comprises a step of forming an anti-reflection layer on the dielectric protection layer and annealing the obtained structure.
